(19) United States
(12) Patent Application Publication
(10) Pub. No.: US 2024/0201948 A1
(43) Pub. Date: Jun. 20, 2024

(54) COMBINED SPARSE AND BLOCK FLOATING ARITHMETIC

(71) Applicant: Advanced Micro Devices, Inc., Santa Clara, CA (US)

(72) Inventor: Gabriel H. Loh, Bellevue, WA (US)

(73) Assignee: Advanced Micro Devices, Inc., Santa Clara, CA (US)

(21) Appl. No.: 18/083,273

(22) Filed: Dec. 16, 2022

(51) Int. Cl. G06F 7/483

(52) U.S. Cl. CPC G06F 7/483

(57) ABSTRACT

A processing device for encoding floating point numbers comprising memory configured to store data comprising the floating point numbers and circuitry. The circuitry is configured to, for a set of the floating point numbers, identify which of the floating point numbers represent a zero value and which of the floating point numbers represent a non-zero value, convert the floating point numbers which represent a non-zero value into a block floating point format value and generate an encoded sparse block floating point format value. The circuitry is also configured to, decode floating point numbers. For an encoded block floating point format value, the circuitry converts the encoded block floating point format value to a set of non-zero floating point numbers based on a sparsity mask previously generated to encode the encoded block floating point format value and generates a non-sparse set of floating point values.

### BACKGROUND

Artificial intelligence applications, such as machine learning (e.g., deep learning) are widely used in a variety of technologies (e.g., image classification). For example, machine learning is used to make predictions or decisions to perform a particular task (e.g., whether an image includes a certain object). Machine learning models are trained in order to make predictions or decisions to perform a particular task (e.g., whether an image includes a certain object). During training, a model is exposed to different data. At each layer, the model transforms the data and receives feedback regarding the accuracy of its operations. During an inference stage, the trained model is used to infer or predict outputs on testing samples (e.g., input tensors).

### BRIEF DESCRIPTION OF THE DRAWINGS

A more detailed understanding can be had from the following description, given by way of example in conjunction with the accompanying drawings wherein:

FIG. 1 is a block diagram of an example device in which one or more features of the disclosure can be implemented;

FIG. 2 is a block diagram of the device of FIG. 1, illustrating additional detail;

FIG. 3 is a flow diagram illustrating an example method of encoding floating point numbers according to features of the disclosure;

FIG. 4 is a block diagram illustrating example circuitry and flow for encoding floating point numbers according to features of the present disclosure;

FIG. 5 is a flow diagram illustrating an example method of decoding floating point numbers according to features of the disclosure;

FIG. 6 is a block diagram illustrating example circuitry and flow for decoding floating point numbers to generate a non-sparse set of block floating point values according to features of the present disclosure; and

FIG. 7 is a block diagram illustrating example circuitry and flow for decoding a sparse block floating point format value to generate a plurality of independent specified non-sparse floating point values according to features of the present disclosure.

### DETAILED DESCRIPTION

Machine learning (e.g., deep learning model) is increasingly being limited by data storage (e.g., memory capacity) and computational throughput. In addition, machine learning typically involves significant memory bandwidth, which can lead to bandwidth bottleneck, negatively impacting performance, and increased power consumption. For example, the amount of memory used to store the activation tensor data at different layers of machine learning neural networks is typically large such that the activation tensor data cannot be saved in on-chip memory depending on the application. That is, storing the activation tensor data typically includes transfer of the data to and from off-chip memory.

Floating point (FP) arithmetic is a technique which represents real numbers as an approximation to support a trade-off between range and precision. In general, a floating-point number is represented approximately with a fixed number of significant bits (i.e., the significand) and scaled using an exponent. FP numbers are frequently used in neural networks to approximate the value of numbers (e.g., numbers in input tensor prior to activation).

The precision and accuracy of a neural network depends on the FP format used to represent numerical values used by the neural network. Precision is reflected by a number of bits used to represent a number. Accuracy in a neural network refers to a level of correctness of a model's prediction (e.g., a ratio of a number of correct predictions to a total number of predictions).

Higher precision formats (e.g., FP32 single precision format which uses 1 bit to represent the sign, 8 bits to represent the exponent and 23 bits to represent the mantissa) can represent a larger dynamic range of numbers with higher resolution than lower precision formats. When a non-zero number (e.g., value between binary 0 and binary 1), represented by an FP format, falls below the floor (i.e., minimal absolute value) of the dynamic range of the FP format, the number is determined as having a value of zero (i.e., vanishing activation), which contributes to inaccuracy of the network. Accordingly, the larger dynamic range and higher resolution of higher precision formats decreases the number of false positives and false negatives (i.e., more precise). However, higher precision formats increase the amount of time, bandwidth, and power used to achieve accurate results compared to lower precision FP formats.

On the other hand, lower precision FP formats (e.g., FP16 half-precision format, which uses 1 bit to represent the sign, 5 bits to represent the exponent and 10 bits to represent the mantissa) typically process inputs more quickly, use less memory and consume less power than higher precision FP formats. However, because lower precision formats can represent a smaller dynamic range of numbers and with lower resolution than higher precision formats, lower precision FP formats typically produce less accurate results than higher precision FP formats, which may not be tolerable for some neural network applications (e.g., applications which benefit from more accurate object detection and classification, such as object detection in computer vision applications such as those applications in the medical field).

Block floating point (BFP) uses fixed point processing to representing non-integer (e.g., fractional) numbers by storing a fixed number of digits of their fractional part. BFP assigns a group of significands (the non-exponent part of the FP number) to a single exponent, rather than a single significand being assigned its own exponent. BFP utilizes the observation that a collection of FP values often do not make use of the entire dynamic range supported by the exponent of typical FP formats. Therefore, instead of storing a separate exponent per value, a single common exponent (stored exponent) is shared by each value within a block. Accordingly, BFP can advantageously limit the amount of data storage needed to perform the same functions as typical FP algorithms by sharing (i.e., reusing) a common exponent across multiple FP values, thereby increasing the efficiency and overall performance of processing various applications (e.g., machine learning applications).

Data sparsity can also be used to increase efficiency and overall performance (e.g., in the machine learning domain). The sparsity of a group of elements (e.g., elements of a feature map) is measured by an amount of zero values of the group of elements. An increase in sparsity of data typically results in an increased compression ratio (e.g., uncompressed data size/compressed data size) of the data because zero values in the data can be sent with less information than non-zero values. The sparsity of the data in the resulting feature maps (i.e., channels) typically differs between feature maps. Accordingly, two adjacent channels can have different levels of sparsity. Typically, there are no intrinsic patterns of sparsity resulting in the data of typical machine learning neural network models.

Features of the present disclosure provide devices and methods for efficiently encoding and decoding FP numbers. The devices and methods described herein further reduce the data size (i.e., further reduce the amount of data to be stored to perform BFP functions) while maintaining tolerable levels of precision and accuracy (e.g., without negatively impacting the effectiveness of training and accuracy of inference). A numerical format is provided which utilizes BFP functionality to directly encode a sparsity map for the values, enabling a larger number of values (e.g., weights, activations) to be encoded in less space. Accordingly, the efficiency and overall performance of processing applications (e.g., machine learning applications) is improved (e.g., less memory bandwidth, increased computational throughput and less data storage).

Features of the present disclosure can be used to encode pixel data values for different portions (e.g., blocks, tiles, or other portion) of an image.

A processing device for encoding floating point numbers is provided which comprises memory configured to store data comprising the floating point numbers and circuitry configured to, for a set of the floating point numbers, identify which of the floating point numbers represent a zero value and which of the floating point numbers represent a non-zero value, convert the floating point numbers representing a non-zero value into a block floating point format value and generate an encoded sparse block floating point format value.

A method for encoding floating point numbers is provided which comprises, for a set of the floating point numbers, identifying which of the floating point numbers represent a zero value and which of the floating point numbers represent a non-zero value, converting the floating point numbers representing a non-zero value into a block floating point format value and generating an encoded sparse block floating point format value.

A processing device for decoding floating point numbers is provided which comprises memory configured to store data comprising the floating point numbers and circuitry configured to, for an encoded block floating point format value, convert the encoded block floating point format value to a set of non-zero floating point numbers based on a sparsity mask previously generated to encode the encoded block floating point format value and generate a non-sparse set of floating point values.

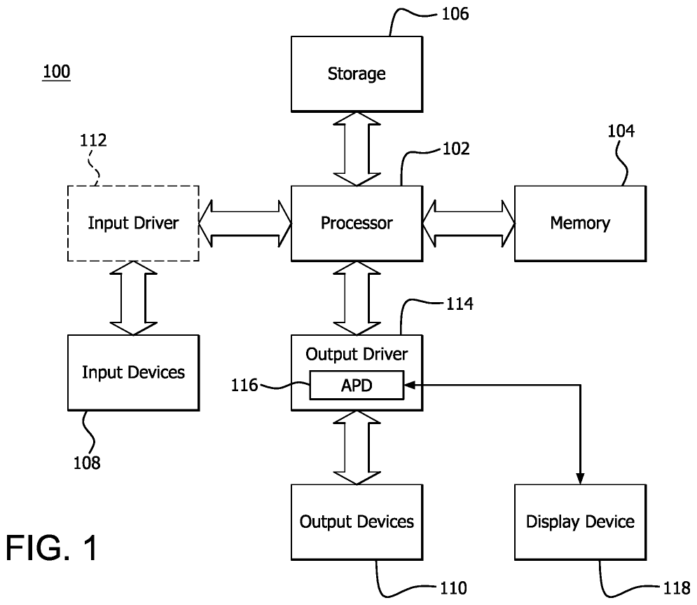

FIG. 1 is a block diagram of an example device 100 in which one or more features of the disclosure can be implemented. The device 100 can include, for example, a computer, a gaming device, a handheld device, a set-top box, a television, a mobile phone, or a tablet computer. The device 100 includes a processor 102, a memory 104, a storage 106, one or more input devices 108, and one or more output devices 110. The device 100 can also optionally include an input driver 112 and an output driver 114. It is understood that the device 100 can include additional components not shown in FIG. 1.

In various alternatives, the processor 102 includes a central processing unit (CPU), a graphics processing unit (GPU), a CPU and GPU located on the same die, or one or more processor cores, wherein each processor core can be a CPU or a GPU or a stand-alone accelerator. In various alternatives, the memory 104 is located on the same die as the processor 102, or is located separately from the processor 102. The memory 104 includes a volatile or non-volatile memory, for example, random access memory (RAM), dynamic RAM, or a cache.

The storage 106 includes a fixed or removable storage, for example, a hard disk drive, a solid state drive, an optical disk, or a flash drive. The input devices 108 include, without limitation, a keyboard, a keypad, a touch screen, a touch pad, a detector, a microphone, an accelerometer, a gyroscope, a biometric scanner, or a network connection (e.g., a wireless local area network card for transmission and/or reception of wireless IEEE 802 signals). The output devices 110 include, without limitation, a display, a speaker, a printer, a haptic feedback device, one or more lights, an antenna, or a network connection (e.g., a wireless local area network card for transmission and/or reception of wireless IEEE 802 signals).

The input driver 112 communicates with the processor 102 and the input devices 108, and permits the processor 102 to receive input from the input devices 108. The output driver 114 communicates with the processor 102 and the output devices 110, and permits the processor 102 to send output to the output devices 110. It is noted that the input driver 112 and the output driver 114 are optional components, and that the device 100 will operate in the same manner if the input driver 112 and the output driver 114 are not present. The output driver 116 includes an accelerated processing device (“APD”) 116 which is coupled to a display device 118. The APD accepts compute commands and graphics rendering commands from processor 102, processes those compute and graphics rendering commands, and provides output to display device 118 for display. As described in further detail below, the APD 116 includes one or more parallel processing units to perform computations in accordance with a single-instruction-multiple-data (“SIMD”) paradigm. Thus, although various functionality is described herein as being performed by or in conjunction with the APD 116, in various alternatives, the functionality described as being performed by the APD 116 is additionally or alternatively performed by other computing devices having similar capabilities that are not driven by a host processor (e.g., processor 102) and provides graphical output to a display device 118. For example, it is contemplated that any processing system that performs processing tasks in accordance with a SIMD paradigm may perform the functionality described herein. Alternatively, it is contemplated that computing systems that do not perform processing tasks in accordance with a SIMD paradigm performs the functionality described herein.

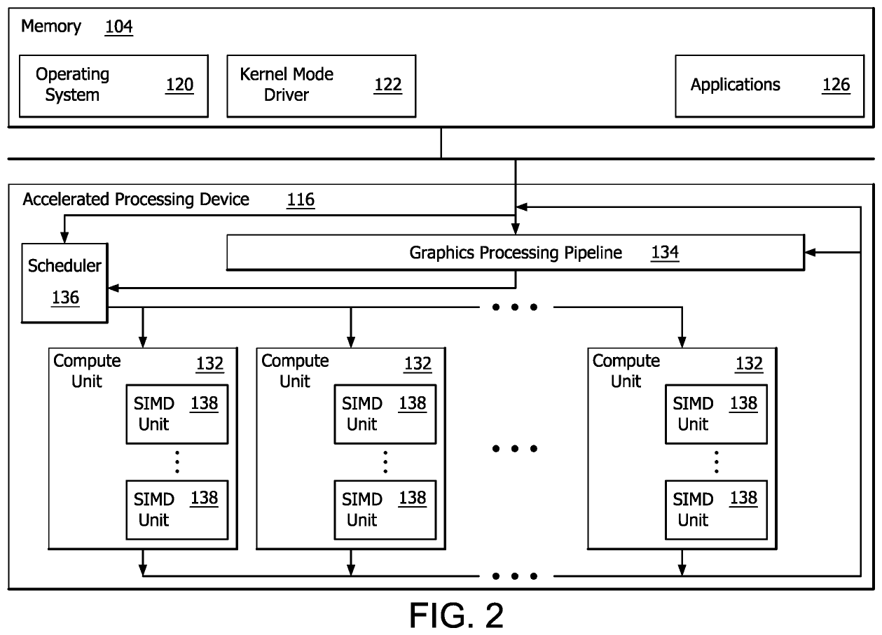

FIG. 2 is a block diagram of the device 100, illustrating additional details related to execution of processing tasks on the APD 116. The processor 102 maintains, in system memory 104, one or more control logic modules for execution by the processor 102. The control logic modules include an operating system 120, a kernel mode driver 122, and applications 126. These control logic modules control various features of the operation of the processor 102 and the APD 116. For example, the operating system 120 directly communicates with hardware and provides an interface to the hardware for other software executing on the processor 102. The kernel mode driver 122 controls operation of the APD 116 by, for example, providing an application programming interface (“API”) to software (e.g., applications 126) executing on the processor 102 to access various functionality of the APD 116. The kernel mode driver 122 also includes a just-in-time compiler that compiles programs for execution by processing components (such as the SIMD units 138 discussed in further detail below) of the APD 116.

The APD 116 executes commands and programs for selected functions, such as graphics operations and non-graphics operations that may be suited for parallel processing. The APD 116 can be used for executing graphics pipeline operations such as pixel operations, geometric computations, and rendering an image to display device 118 based on commands received from the processor 102. The APD 116 also executes compute processing operations that are not directly related to graphics operations, such as operations related to video, physics simulations, computational fluid dynamics, or other tasks, based on commands received from the processor 102.

The APD 116 includes compute units 132 that include one or more SIMD units 138 that perform operations at the request of the processor 102 in a parallel manner according to a SIMD paradigm. The SIMD paradigm is one in which multiple processing elements share a single program control flow unit and program counter and thus execute the same program but are able to execute that program with different data. In one example, each SIMD unit 138 includes sixteen lanes, where each lane executes the same instruction at the same time as the other lanes in the SIMD unit 138 but can execute that instruction with different data. Lanes can be switched off with predication if not all lanes need to execute a given instruction. Predication can also be used to execute programs with divergent control flow. More specifically, for programs with conditional branches or other instructions where control flow is based on calculations performed by an individual lane, predication of lanes corresponding to control flow paths not currently being executed, and serial execution of different control flow paths allows for arbitrary control flow.

The basic unit of execution in compute units 132 is a work-item. Each work-item represents a single instantiation of a program that is to be executed in parallel in a particular lane. Work-items can be executed simultaneously as a “wavefront” on a single SIMD processing unit 138. One or more wavefronts are included in a “work group,” which includes a collection of work-items designated to execute the same program. A work group can be executed by executing each of the wavefronts that make up the work group. In alternatives, the wavefronts are executed sequentially on a single SIMD unit 138 or partially or fully in parallel on different SIMD units 138. Wavefronts can be thought of as the largest collection of work-items that can be executed simultaneously on a single SIMD unit 138. Thus, if commands received from the processor 102 indicate that a particular program is to be parallelized to such a degree that the program cannot execute on a single SIMD unit 138 simultaneously, then that program is broken up into wavefronts which are parallelized on two or more SIMD units 138 or serialized on the same SIMD unit 138 (or both parallelized and serialized as needed). A scheduler 136 performs operations related to scheduling various wavefronts on different compute units 132 and SIMD units 138.

The parallelism afforded by the compute units 132 is suitable for graphics related operations such as pixel value calculations, vertex transformations, and other graphics operations. Thus in some instances, a graphics pipeline 134, which accepts graphics processing commands from the processor 102, provides computation tasks to the compute units 132 for execution in parallel.

The compute units 132 are also used to perform computation tasks not related to graphics or not performed as part of the “normal” operation of a graphics pipeline 134 (e.g., custom operations performed to supplement processing performed for operation of the graphics pipeline 134). An application 126 or other software executing on the processor 102 transmits programs that define such computation tasks to the APD 116 for execution.

The APD 116 is configured to execute machine learning models, including deep learning models. The APD 116 is configured to store activation tensor data at different layers of machine learning neural networks. The APD 116 is configured to perform, at each layer, operations (e.g., convolution kernel, pooling operation) to input data (e.g., image, activation tensors) of a previous layer and apply filters to the input data to provide tensor data for the next layer.

As described above, the amount of memory used to store the activation tensor data at different layers of neural networks is typically large (e.g., in the early layers) such that the activation tensor data cannot be saved in on-chip memory (e.g., memory at the APD 116). Accordingly, storing the activation tensor data includes transfer of the data between the APD 116 and off-chip memory (e.g., memory 104) via a link (e.g., a bus). The APD 116 is configured to encode (e.g., compress) and decode FP numbers and other data to be transferred to off-chip memory (e.g., save bandwidth).

As described above, features of the present disclosure further reduce the data size (i.e., further reduce the amount of data to be stored to perform BFP functions) while maintaining tolerable levels of precision and accuracy (e.g., without negatively impacting the effectiveness of training and accuracy of inference).

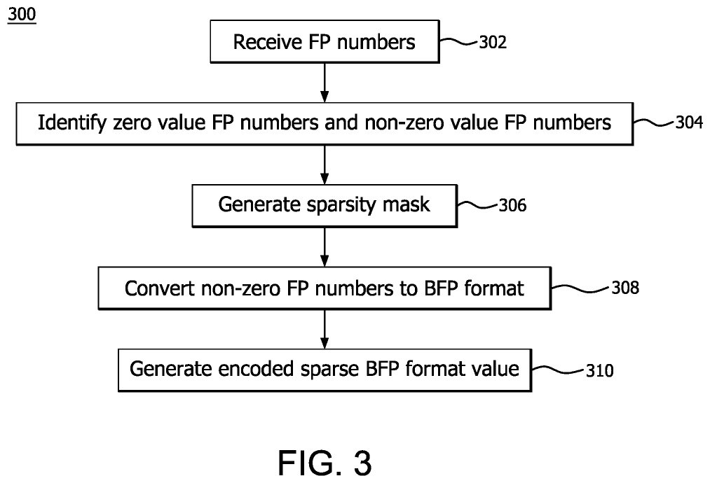

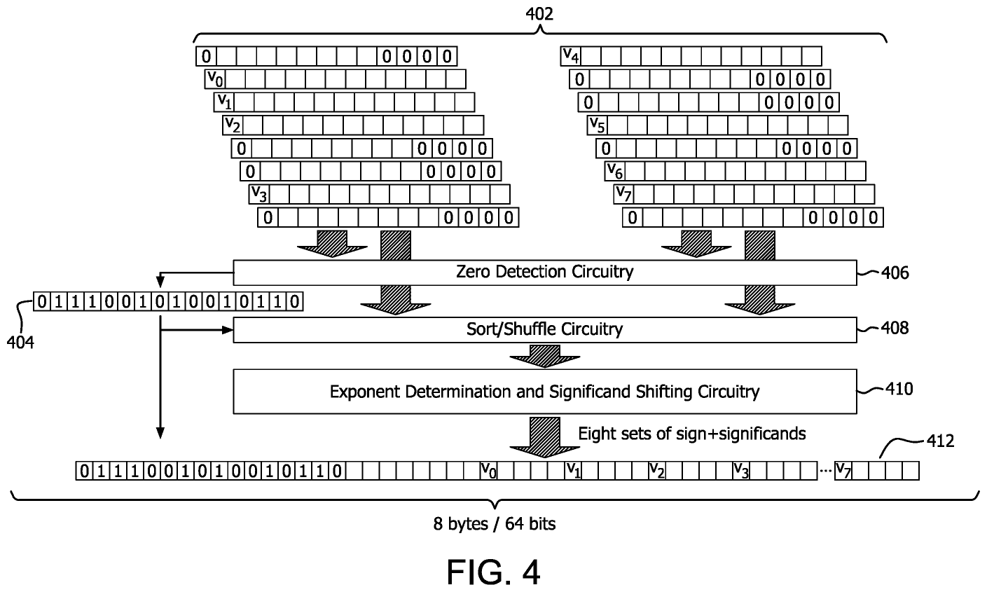

FIG. 3 is a flow diagram illustrating an example method of encoding (packing) FP numbers according to features of the disclosure. FIG. 4 is a block diagram illustrating an example circuitry and flow for encoding FP numbers according to features of the present disclosure. The block diagram shown in FIG. 4 is used to describe the method 300 in FIG. 3. Examples of hardware circuitry shown in FIG. 4 include zero detection circuitry 406, sort/shuffle circuitry 408 and exponent determination and significand shifting circuitry 410. Each portion of the example hardware circuitry shown in FIG. 4 includes, for example, at least one of hardware logic gates and a processor (e.g., processor 102, APD 116, a CPU, a GPU, an AI accelerator or field-programmable gate array (FPGA)).

The method 300 utilizes BFP functionality to encode a sparsity map for the values, enabling a larger number of values (e.g., weights, activations) to be encoded in less space, thereby improving the efficiency and overall performance of processing applications (e.g., machine learning applications).

As shown at block 302, the method 300 includes receiving a plurality of FP numbers. The FP numbers are received, for example, at zero detection circuitry.

The example shown in FIG. 4 includes a set of 16 FP numbers 402 with each of the FP numbers 402 of the set comprising 13 bits to represent its corresponding value. However, features of the present disclosure can be implemented for any amount of FP numbers (i.e., different than 16 FP numbers) each having a number of bits different from the 13 bits shown in FIG. 4.

The significand bits (i.e., the last 4 bits) of an FP number define whether the FP number represents a zero value or a non-zero value. For simplicity, the FP numbers 402 which represent a zero value are shown in FIG. 4 with a sign bit value of zero. However, the sign bits of these FP numbers 402 can also have a sign bit value of 1. For simplicity, the remaining FP numbers 402 which represent a non-zero value are shown in FIG. 4 with one of the values V₀ to V₇ in the sign bit position and the significand bits of these FP numbers 402 which represent a non-zero value are shown without any bit values.

As shown at block 304, the method 300 includes identifying which FP numbers 402 represent a zero value and which FP numbers 402 represent a non-zero value. For example, the 16 FP numbers 402 are received, for example, by zero detection hardware circuitry 406 (e.g., circuitry comprising a processor and/or logic gates of a CPU, GPU, AI accelerator or field-programmable gate array (FPGA)), which identifies the FP numbers 402 representing a zero value and the FP numbers 402 representing a non-zero value.

In the example shown at FIG. 4, 8 of the 16 FP numbers 402 represent a non-zero value and 8 of the 16 FP numbers 402 represent a zero value (i.e., a sparsity factor of 2). However, features of the present disclosure can be used to encode a set of FP numbers having a sparsity factor different than the sparsity factor of the FP numbers 402 in FIG. 4.

As shown at block 306, the method 300 includes generating a sparsity mask (i.e., vector mask) 404 which indicates (i.e., represents), via a single bit value of 0 or 1 for each FP number 402, the FP numbers 402 identified as representing a zero value and the FP numbers 402 identified as representing a non-zero value. For example, as shown in FIG. 4, each of the FP numbers 402 having a zero value are represented by a bit value 0 in the sparsity mask 404 and each of the FP numbers 402 having a non-zero value are represented by a bit value of 1 in the sparsity mask 404. The first bit (i.e., value of 0) in the sparsity mask 404 corresponds to the first FP number 402 representing a zero value. Therefore, no further bits are needed to store the value of the first FP number 402. The second bit (i.e., value of 1) in the sparsity mask 404 corresponds to the second FP number 402 (V₀) which represents a non-zero value. Each of the remaining bits in the sparsity mask 404 include a bit value (0 or 1) for the corresponding FP number 402, ending with the last bit (i.e., value of 0) in the sparsity mask 404 corresponding to the last FP number 402 having a zero value.

The sparsity mask 404 mask is provided to the sort/shuffle circuitry 408 as well as to the BFP format value 412, which includes the 8 non-zero 13-bit BFP numbers (i.e., BFP13-8-S2 format) converted from the 16 13-bit FP numbers 402, having a sparsity factor of 2.

The sort/shuffle circuitry 408 encodes the 16 13-bit FP numbers 402 to 8 non-zero value FP numbers by storing the 8 FP numbers 402 indicated by the sparsity mask 404 as representing a zero value as a single bit value of 0 in the memory. When there are fewer than 8 non-zero values, then the remaining unused sign and significand bits can be set to zero or to some other arbitrary value. When there are greater than 8 non-zero values, the circuitry can issue an error signal, or it can output an “invalid” or “unencoded output” (e.g., such as the format where the sparsity mask is set to all 1s). By storing each of the FP numbers indicated as representing a zero value in the memory

As shown at block 308, the method 300 includes converting the non-zero FP numbers to BFP format. For example, the 8 non-zero value FP numbers are provided to the exponent determination and significand shifting circuitry 410, which converts the 8 non-zero value FP numbers into a BFP format. The exponent determination and significand shifting circuitry 410 compares the exponents from each of the 8 non-zero value FP numbers, determines a value for the shared exponent, and adjusts the significands (i.e., mantissas) to align with the new shared exponent value. Accordingly a single exponent value is stored for each of the values.

The shared exponent is, for example, determined by selecting the exponent value from among the 8 non-zero value FP numbers that has the largest (e.g., maximum) exponent value. Then, for each non-zero value FP number, the significand is right-shifted (i.e., reduced in magnitude) by a number of bits equal to the difference between the selected shared exponent value (e.g., largest exponent value) and its corresponding original exponent value. For example, if a non-zero value FP number is originally represented as 24*2⁵ (significand of 24 and exponent of 5), but the selected shared maximum exponent value is 6, then the significand is adjusted by right shifting by one bit (i.e., the difference between the selected shared exponent value and its corresponding original exponent value (6−5=1)), which is the equivalent of dividing by two and which results in a significand equal to a value of 24/2=12. When paired with the selected shared exponent, the non-zero value is encoded as 12*2⁶, which is numerically equal to its original value of 24*2⁵.

As shown at block 310, the method 300 includes generating an encoded sparse BFP format value, by combining the sparsity mask 404 with the BFP output (i.e., the converted 8 non-zero value FP numbers) provided at block 308. For example, the sparsity mask, the shared exponent, and the 8 sets of sign and significand bits are outputted from the determination and significand shifting circuitry 410 to provide the encoded BFP format value 412 (e.g., the 8 non-zero 13-bit BFP numbers converted from the 16 13-bit FP numbers 402.

In the example shown in FIG. 4, the 16 13-bit FP numbers 402, having a sparsity factor of 2, are converted to 8 non-zero 13-bit BFP numbers (i.e., BFP13-8-S2 format). In the example, the combination of the sparsity mask 404, the shared exponent value, and the 8 sets of sign and significands add up to 64 bits (8 bytes), which matches the datapath width of typical processors (e.g., 64-bit CPUs, 64-bit GPU datapaths) and cache load/store interfaces. However, features of the present disclosure can be implemented for other values, such as a different degree of sparsity (e.g., S=4), a larger amount of FP numbers (e.g., 32 FP numbers), different exponent sizes and different significand sizes than those shown in FIG. 4.

In addition, in the example shown in FIG. 4, 8 bits are the maximum amount of non-zero values supported in the sparsity mask. However, features of the present disclosure can be implemented for less than 8 non-zero values (i.e., a higher level of sparsity) in the sparsity mask. In these cases, one or more of the sign and significand bits may go unused and can be set to zero, or left at some other value, or repurposed for other uses. Because there is a limit on the number of bit values equal to 1 that can be set in the sparsity mask (e.g., 8 in the example shown in FIG. 4), a sparsity mask can be used to encode additional information. For example, each of the bits can be set to 1 to indicate that the block of 16 values could not be encoded in the sparse format (e.g., more than 8 of the 16 values represented non-zero values) and the bits can be treated as a normal non-sparse set of eight BFP values.

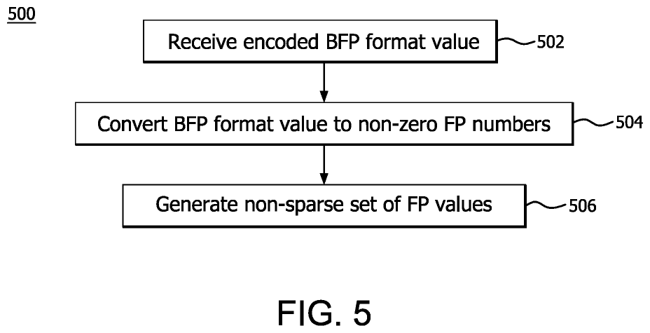

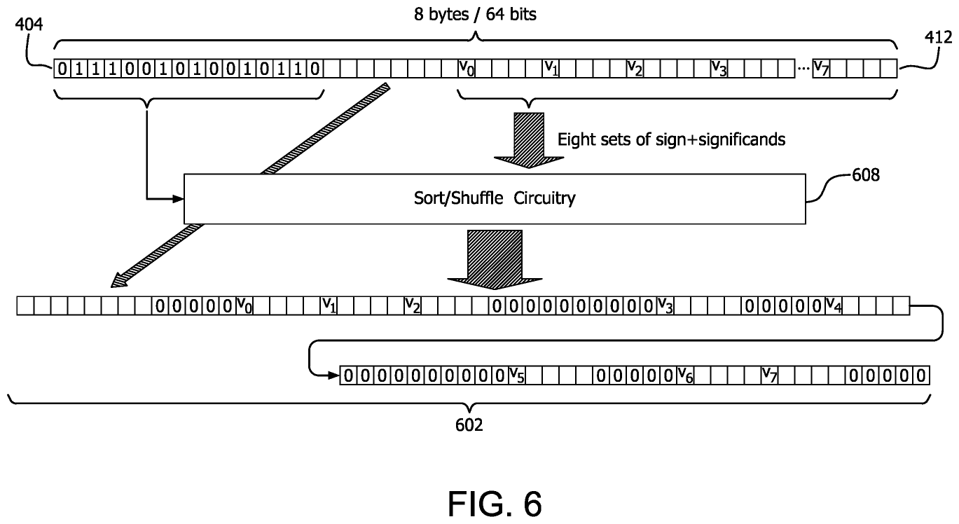

FIG. 5 is a flow diagram illustrating an example method 500 of decoding (unpacking) FP numbers according to features of the disclosure. FIG. 6 is a block diagram illustrating example circuitry and flow for decoding FP numbers to generate a non-sparse set of BFP values according to features of the present disclosure. The block diagram shown in FIG. 6 is used to describe the method 500 in FIG. 5.

As shown at block 502, the method 500 includes receiving an encoded sparse BFP format value. For example, as shown in FIG. 6, the encoded sparse BFP format value 412 is provided to sort/shuffle circuitry 608. The sort/shuffle circuitry 608 shown in FIG. 6 includes, for example, at least one of hardware logic gates and a processor (e.g., processor 102, APD 116 a CPU, a GPU, an AI accelerator or field-programmable gate array (FPGA)). The sort/shuffle circuitry 608 includes, for example, the same or similar circuitry as the sort/shuffle circuitry 408 shown in FIG. 4.

As shown at block 504, the method 500 includes converting the BFP format value to non-zero FP numbers. For example, the BFP format value is converted by sort/shuffle circuitry 608 based on (1) the sparsity mask 404 that was previously generated to encode the sparse BFP format value 412 and (2) the zero value FP numbers previously identified by the bits in the sparsity mask 404.

As shown at block 506, the method 500 includes generating a non-sparse set of FP values. The non-sparse set of FP values can be generated as a non-sparse set of BFP values. For example, as shown in FIG. 6, the encoded sparse BFP format value 412 (as described above in FIG. 4) is decoded into a non-sparse set of 16 BFP values 602. Each zero value encoded by a zero-bit in the sparsity mask 404 is expanded into a set of zero sign+significand bits.

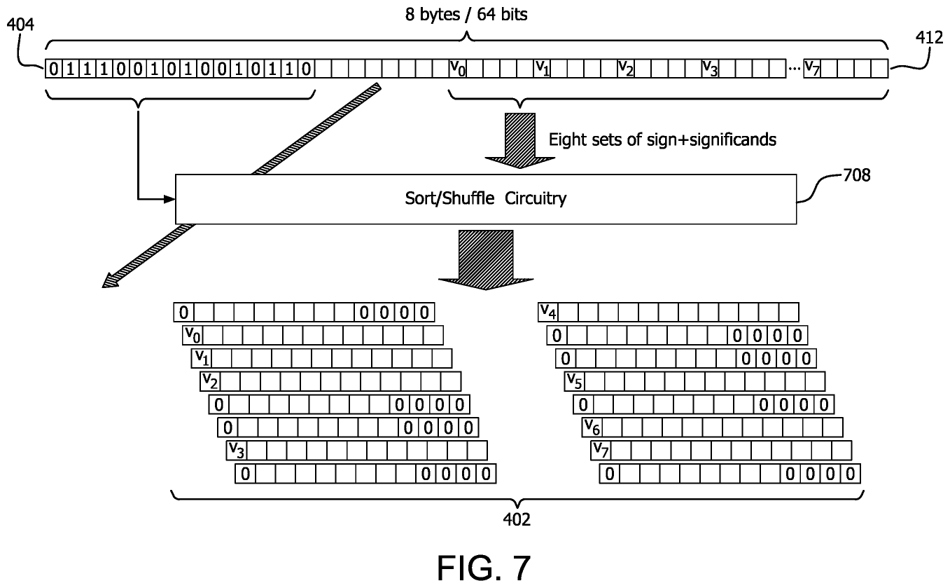

Alternatively, the encoded sparse BFP format value 412 is decoded into a non-sparse set of independent specified values. For example, FIG. 7 is a block diagram illustrating example circuitry and flow for decoding a sparse BFP format value to generate independent specified non-sparse BFP values according to features of the present disclosure. The sort/shuffle circuitry 708 shown in FIG. 7 includes, for example, at least one of hardware logic gates and a processor (e.g., processor 102, APD 116 a CPU, a GPU, an AI accelerator or field-programmable gate array (FPGA)). The sort/shuffle circuitry 708 includes, for example, the same or similar circuitry as the sort/shuffle circuitry 408 shown in FIG. 4 and the sort/shuffle circuitry 608 shown in FIG. 6.

As shown in FIG. 7, sort shuffle circuitry 708 decodes the sparse BFP format value 412 to generate the 16 independent specified non-sparse BFP values 402 shown in FIG. 4.

The resulting independent specified non-sparse BFP values 402 can then be directly added by a SIMD/vector set of adders. Information, such as rendered image data (e.g., chrominance and luminance values of pixels) which is derived from the decoded FP numbers, is then provided for display on a display device (e.g., display device 118).

Features of the present disclosure can be made to be compatible with existing BFP formats, which reduces the hardware overhead required to support the combined sparse-BFP format.

Features of the present disclosure can be implemented to provide datatypes which match various typically used hardware datapaths (e.g., the 64-bit format) in a more useful fashion.

It should be understood that many variations are possible based on the disclosure herein. Although features and elements are described above in particular combinations, each feature or element can be used alone without the other features and elements or in various combinations with or without other features and elements.

The various functional units illustrated in the figures and/or described herein (including, but not limited to, the processor 102, the input driver 112, the input devices 108, the output driver 114, the output devices 110, the accelerated processing device 116, the scheduler 136, the graphics processing pipeline 134, the compute units 132, the SIMD units 138, the zero detection circuitry 406, the sort/shuffle circuitry 408, 608 and 708, and the exponent determination and significand shifting circuitry 410 may be implemented as a general purpose computer, a processor, or a processor core, or as a program, software, or firmware, stored in a non-transitory computer readable medium or in another medium, executable by a general purpose computer, a processor, or a processor core. The methods provided can be implemented in a general purpose computer, a processor, or a processor core. Suitable processors include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Such processors can be manufactured by configuring a manufacturing process using the results of processed hardware description language (HDL) instructions and other intermediary data including netlists (such instructions capable of being stored on a computer readable media). The results of such processing can be maskworks that are then used in a semiconductor manufacturing process to manufacture a processor which implements features of the disclosure.

The methods or flow charts provided herein can be implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A processing device for encoding floating point numbers comprising:
memory configured to store data comprising the floating point numbers; and
circuitry configured to, for a set of the floating point numbers:
identify which of the floating point numbers represent a zero value and which of the floating point numbers represent a non-zero value;
convert the floating point numbers representing a non-zero value into a block floating point format value; and
generate an encoded sparse block floating point format value.

2. The processing device of claim 1, wherein the circuitry is configured to generate a sparsity mask which indicates, via a single bit value for each floating point number in the set of floating point numbers, the floating point numbers identified as representing a zero value and the floating point numbers identified as representing a non-zero value.

3. The processing device of claim 2, wherein the circuitry is configured to generate the encoded sparse block floating point format value by combining the sparsity mask and the block floating point format value.

4. The processing device of claim 2, wherein the circuitry is configured to encode the floating point numbers indicated by the sparsity mask as representing a zero value by storing each of the floating point numbers indicated as representing a zero value as a single bit in the memory.

5. The processing device of claim 1, wherein the circuitry is configured to convert the floating point numbers representing a non-zero value into a block floating point format by:
comparing exponents from each of the floating point numbers representing a non-zero value,
determining a shared exponent value; and
adjusting significands of the floating point numbers representing a non-zero value.

6. The processing device of claim 5, wherein the circuitry is configured to determine the shared exponent value by selecting an exponent value having a largest value among the exponent values of each of the floating point numbers representing a non-zero value.

7. The processing device of claim 6, wherein the circuitry is configured to adjust the significands of the floating point numbers representing a non-zero value by shifting, for each floating point number representing a non-zero value, the significands by an amount of bits equal to a difference between the selected exponent value and its corresponding exponent value.

8. The processing device of claim 5, wherein the circuitry comprises at least one of hardware logic gates and a processor.

9. A method for encoding floating point numbers comprising:
for a set of the floating point numbers:
identifying which of the floating point numbers represent a zero value and which of the floating point numbers represent a non-zero value;
converting the floating point numbers representing a non-zero value into a block floating point format value; and
generating an encoded sparse block floating point format value.

10. The method of claim 9, further comprising generating a sparsity mask which indicates, via a single bit value for each floating point number in the set of the floating point numbers, the floating point numbers identified as representing a zero value and the floating point numbers identified as representing a non-zero value.

11. The method of claim 10, further comprising generating the encoded sparse block floating point format value by combining the sparsity mask and the block floating point format value.

12. The method of claim 10, further comprising encoding the floating point numbers indicated by the sparsity mask as representing a zero value by storing each of the floating point numbers indicated as representing a zero value as a single bit.

13. The method of claim 9, further comprising converting the floating point numbers which represent a non-zero value into a block floating point format by:
comparing exponents from each of the floating point numbers representing a non-zero value,
determining a shared exponent value; and
adjusting significands of the floating point numbers representing a non-zero value.

14. The method of claim 13, further comprising determining the shared exponent value by selecting an exponent value having a largest value among the exponent values of each of the floating point numbers representing a non-zero value.

15. The method of claim 14, further comprising adjusting the significands of the floating point numbers representing a non-zero value by shifting, for each floating point number representing a non-zero value, the significands by an amount of bits equal to a difference between the selected exponent value and its corresponding exponent value.

16. A processing device for decoding floating point numbers comprising:
memory configured to store data comprising the floating point numbers; and
circuitry configured to, for an encoded block floating point format value:
convert the encoded block floating point format value to a set of non-zero floating point numbers based on a sparsity mask previously generated to encode the encoded block floating point format value; and
generate a non-sparse set of floating point values.

17. The processing device of claim 16, wherein the circuitry is configured to convert the encoded block floating point format value to the set of non-zero floating point numbers based on zero value floating point numbers previously identified by bits in the sparsity mask.

18. The processing device of claim 16, wherein the non-sparse set of floating point values is a non-sparse set of block floating point values.

19. The processing device of claim 16, wherein the non-sparse set of floating point values is a non-sparse set of independent specified floating point values.

20. The processing device of claim 16, further comprising a display device configured to display information derived from the floating point numbers.
